(19) United States
(12) Patent Application Publication
(10) Pub. No.: US 2025/0286516 A1
(43) Pub. Date: Sep. 11, 2025

(54) RESISTIVE CIRCUIT THAT REDUCES INFLUENCE OF WELL BIAS EFFECT AND MANUFACTURING METHOD THEREOF AND AMPLIFIER CIRCUIT

(71) Applicant: REALTEK SEMICONDUCTOR CORP., HSINCHU (TW)

(72) Inventors: Hsu-ming Tsai, HSINCHU (TW); Wei-Cheng Tang, HSINCHU (TW); CHIA-LING CHANG, HSINCHU (TW)

(21) Appl. No.: 18/965,001

(22) Filed: Dec. 2, 2024

(30) Foreign Application Priority Data
Mar. 7, 2024 (TW) 113108257

(51) Int. Cl. H03F 1/26

(52) U.S. Cl. CPC H03F 1/26; H03F 2200/21

(57) ABSTRACT

A resistive circuit and a manufacturing method thereof and an amplifier circuit are provided. The resistive circuit includes one or more first resistive elements and one or more second resistive elements. The one or more first resistive elements are arranged in series or in parallel along a first path, and the one or more second resistive elements are arranged in series or in parallel along a second path. The one or more first resistive elements and the one or more second resistive elements are connected in parallel between a first node and a second node. Each of the first resistive element and the second resistive element include a well region, the well region of each of first resistive elements is connected to the first node, and the well region of each of the second resistive elements is connected to the second node.

### CROSS-REFERENCE TO RELATED PATENT APPLICATION

This application claims the benefit of priorities to Taiwan Patent Application No. 113108257, filed on Mar. 7, 2024. The entire content of the above identified application is incorporated herein by reference.

Some references, which may include patents, patent applications and various publications, may be cited and discussed in the description of this disclosure. The citation and/or discussion of such references is provided merely to clarify the description of the present disclosure and is not an admission that any such reference is “prior art” to the disclosure described herein. All references cited and discussed in this specification are incorporated herein by reference in their entireties and to the same extent as if each reference was individually incorporated by reference.

### FIELD OF THE DISCLOSURE

The present disclosure relates to a resistive circuit and a manufacturing method thereof and an amplifier circuit, and more particularly to a resistive circuit that reduces an influence of a well bias effect and a manufacturing method thereof and an amplifier circuit.

### BACKGROUND OF THE DISCLOSURE

A resistor used in a chip has a well region. When the resistor is used in a circuit structure to receive a signal, node voltages at first and second nodes of the resistor changes with the received signal, and an average value of a first voltage difference between the well region and the first node and a second voltage difference between the well region and the second node also changes with the received signal, which causes the resistance value of the resistor to be non-constant.

Because the resistance value of the resistor changes with the average value of the first and second voltage differences, a serious total harmonic distortion can occur, making circuit design more difficult.

### SUMMARY OF THE DISCLOSURE

In response to the above-referenced technical inadequacy, the present disclosure provides a resistive circuit that reduces the influence of the well bias effect. The resistive circuit includes one or a plurality of first resistive elements and one or a plurality of second resistive elements. The one or the plurality of first resistive elements is arranged in series or in parallel along a first path. The one or the plurality of second resistive elements is arranged in series or in parallel along a second path. The one or the plurality of first resistive elements arranged in series or in parallel along the first path and the one or the plurality of second resistive elements arranged in series or in parallel along the second path are connected in parallel between a first node and a second node. Each of the one or the plurality of first resistive elements and the one or the plurality of second resistive elements include a well region, the well region of each of the plurality of first resistive elements is connected to the first node, and the well region of each of the plurality of second resistive elements is connected to the second node.

In order to solve the above-mentioned problem, one of the technical aspects adopted by the present disclosure is to provide an amplifier circuit. The amplifier circuit includes an operational amplifier, one or a plurality of first resistors and one or a plurality of second resistors. The operational amplifier includes a first input terminal, a second input terminal and an output terminal. The one or the plurality of first resistors is connected between the first input terminal and a signal input node. The one or the plurality of second resistors is connected between the first input terminal and the output terminal. Each of the one or the plurality first resistors and the one or the plurality of second resistors includes one or a plurality of first resistive elements and one or a plurality of second resistive elements. The one or the plurality of first resistive elements are arranged along a first path. The one or the plurality of second resistive elements are arranged along a second path. The one or the plurality of first resistive elements arranged along the first path and the one or the plurality of second resistive elements arranged along the second path are connected in parallel between a first node and a second node. Each of the one or the plurality of first resistive elements and the one or the plurality of second resistive elements include a well region, the well region of each of the plurality of first resistive elements is connected to the first node, and the well region of each of the plurality of second resistive elements is connected to the second node.

In order to solve the above-mentioned problem, another one of the technical aspects adopted by the present disclosure is to provide a manufacturing method of a resistive circuit that reduces the influence of the well bias effect. The manufacturing method of the resistive circuit includes: arranging one or a plurality of first resistive elements in series or parallel along a first path; arranging one or a plurality of second resistive elements in series or parallel along a second path; connecting the one or the plurality of first resistive elements arranged in series or parallel along the first path and the one or the plurality of second resistive elements arranged in series or parallel along the second path in parallel between a first node and a second node, each of the one or the plurality of first resistive elements and the one or the plurality of second resistive elements including a well region; connecting the well region of each of the one or the plurality of first resistive elements to the first node; and connecting the well region of each of the one or the plurality of second resistive elements to the second node.

Therefore, in the resistive circuit that reduces the influence of the well bias effect, the manufacturing method of the resistive circuit and the amplifier circuit provided by the present disclosure, the impact of the well bias effect on a resistance value of the resistive element can be reduced, such that the difficulty of chip design can be reduced.

These and other aspects of the present disclosure will become apparent from the following description of the embodiment taken in conjunction with the following drawings and their captions, although variations and modifications therein may be affected without departing from the spirit and scope of the novel concepts of the disclosure.

### BRIEF DESCRIPTION OF THE DRAWINGS

The described embodiments may be better understood by reference to the following description and the accompanying drawings, in which:

FIG. 1 is a circuit diagram of a resistive circuit that reduces an influence of a well bias effect according to a first embodiment of the present disclosure;

FIG. 2 is a circuit diagram of a resistive circuit that reduces the influence of the well bias effect according to a second embodiment of the present disclosure;

FIG. 3 is a circuit diagram of a resistive circuit that reduces the influence of the well bias effect according to a third embodiment of the present disclosure;

FIG. 4 is a flowchart of a manufacturing method of a resistive circuit that reduces the influence of the well bias effect according to one embodiment of the present disclosure;

FIG. 5 is a circuit diagram of an amplifier circuit according to a first embodiment of the present disclosure;

FIG. 6 is a circuit diagram of an amplifier circuit according to a second embodiment of the present disclosure;

FIG. 7 is a circuit diagram of an amplifier circuit according to a third embodiment of the present disclosure.

### DETAILED DESCRIPTION OF THE EXEMPLARY EMBODIMENTS

The present disclosure is more particularly described in the following examples that are intended as illustrative only since numerous modifications and variations therein will be apparent to those skilled in the art. Like numbers in the drawings indicate like components throughout the views. As used in the description herein and throughout the claims that follow, unless the context clearly dictates otherwise, the meaning of “a,” “an” and “the” includes plural reference, and the meaning of “in” includes “in” and “on.” Titles or subtitles can be used herein for the convenience of a reader, which shall have no influence on the scope of the present disclosure.

The terms used herein generally have their ordinary meanings in the art. In the case of conflict, the present document, including any definitions given herein, will prevail. The same thing can be expressed in more than one way. Alternative language and synonyms can be used for any term(s) discussed herein, and no special significance is to be placed upon whether a term is elaborated or discussed herein. A recital of one or more synonyms does not exclude the use of other synonyms. The use of examples anywhere in this specification including examples of any terms is illustrative only, and in no way limits the scope and meaning of the present disclosure or of any exemplified term. Likewise, the present disclosure is not limited to various embodiments given herein. Numbering terms such as “first,” “second” or “third” can be used to describe various components, signals or the like, which are for distinguishing one component/signal from another one only, and are not intended to, nor should be construed to impose any substantive limitations on the components, signals or the like.

FIG. 1 is a circuit diagram of a resistive circuit that reduces an influence of a well bias effect according to a first embodiment of the present disclosure. Referring to FIG. 1, a resistive circuit 1 includes a first resistive element R1 and a second resistive element R2. The first resistive element R1 and the second resistive element R2 are, for example, polycrystalline silicon resistors, but the present disclosure is not limited thereto.

The first resistive element R1 and the second resistive element R2 have the same resistance value under a predetermined condition. Specifically, the first resistive element R1 and the second resistive element R2 have the same rated resistance value or nominal resistance value.

The first resistive element R1 and the second resistive element R2 are respectively arranged along a first path L1 and a second path L2, and the first resistive element R1 arranged along the first path L1 and the second resistive element R2 arranged along the second path L2 are connected in parallel between a first node N1 and a second node N2. The first resistive element R1 includes a first well region W1, and the second resistive element R2 includes a second well region W2. The first well region W1 is connected to the first node N1, and the second well region W2 is connected to the second node N2.

For example, a voltage of the first node N1 is V1, a voltage of the second node N2 is V2, a voltage of a well region is Vwell, and the rated resistance values of the first resistive element R1 and the second resistive element R2 are K. A first resistance value of the first resistive element R1 considering a bias voltage at two ends of the first resistive element R1 is K1, and a second resistance value of the second resistive element R2 considering the bias voltage at two ends of the second resistive element R2 is K2.

K1=K*(1+VB_{coeff}*[(V1−Vwell)+(V2−Vwell)]/2)−K*(1+VB_{coeff}*(V2−V1)/2), VB_{coeff} is constant, and Vwell=V1.

K2=K*(1+VB_{coeff}*[(V1−Vwell)+(V2−Vwell)]/2)−K*(1+VB_{coeff}*(V1−V2)/2), VB_{coeff} is constant, and Vwell=V2.

$$K 1 // K 2 = ( K 1 * K 2 ) / ( K 1 + K 2 ) = K / 2 * ( 1 - {VB}_{coeff}^{2} * {( V 2 - V 1 )}^{2} / 4 ) .$$

$$K 1 // K 2 ≅ K / 2 .$$

It can be seen from the above formulas that when the first well region W1 of the first resistive element R1 and the second well region W2 of the second resistive element R2 are respectively connected to the first node N1 and the second node N2, the well bias effects on the resistance values of the first resistive element R1 and the second resistive element R2 can be reduced.

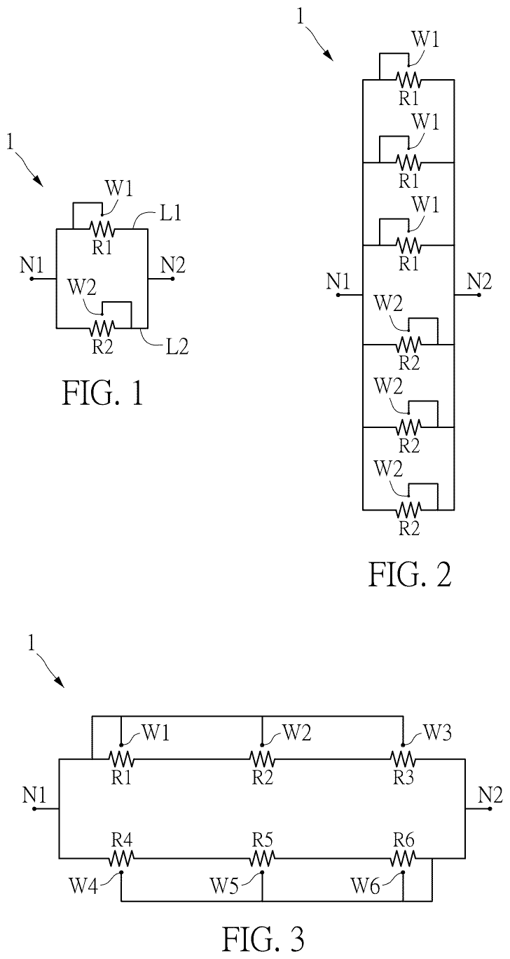

FIG. 2 is a circuit diagram of a resistive circuit that reduces the influence of the well bias effect according to a second embodiment of the present disclosure. Referring to FIG. 2, the resistive circuit 1 includes a plurality of first resistive elements R1 and a plurality of second resistive elements R2. Each of the first resistive elements R1 and each of the second resistive elements R2 have the same resistance value under the predetermined condition. Specifically, each of the first resistive elements R1 and each of the second resistive elements R2 have the same rated resistance value or nominal resistance value.

The plurality of first resistive elements R1 and the plurality of second resistive elements R2 are connected in parallel between the first node N1 and the second node N2. Each of the first resistive elements R1 includes a first well region W1, and each of the second resistive elements R2 includes a second well region W2. Each of the first well regions W1 is connected to the first node N1, and each of the second well regions W2 is connected to the second node N2.

FIG. 3 is a circuit diagram of a resistive circuit that reduces influence of well bias effect according to a third embodiment of the present disclosure. Referring to FIG. 3, the resistive circuit 1 includes the first resistive element R1, the second resistive element R2, a third resistive element R3, a fourth resistive element R4, a fifth resistive element R5 and a sixth resistive element R6. The first resistive element R1 and the second resistive element R2, the third resistive element R3, the fourth resistive element R4, the fifth resistive element R5 and the sixth resistive element R6 are, for example, polycrystalline silicon resistors, but the present disclosure is not limited thereto.

The first resistance value of the first resistive element R1, the second resistance value of the second resistive element R2 and a third resistance value of the third resistive element R3 respectively correspond to a fourth resistance value of the fourth resistive element R4, a fifth resistance value of the fifth resistive element R5, and a sixth resistance value of the sixth resistive element R6 under the predetermined condition.

For example, the first resistance value, the second resistance value, the third resistance value, the fourth resistance value, the fifth resistance value and the sixth resistance value are all the same.

In another example, the first resistance value, the second resistance value, and the third resistance value are not all the same, in which the first resistance value is the same as the fourth resistance value, the second resistance value is the same as the fifth resistance value, and the third resistance value is the same as sixth resistance value.

The first resistive element R1, the second resistive element R2, and the third resistive element R3 are arranged along the first path L1 in series, while the fourth resistive element R4, the fifth resistive element R5, and the sixth resistive element R6 are arranged along the second path L2 in series. The first resistive element R1, the second resistive element R2, the third resistive element R3 arranged along the first path L1 in series, and the fourth resistive element R4, the fifth resistive element R5, the sixth resistive element R6 arranged along the second path L2 in series are connected in parallel between the first node N1 and the second node N2.

The first resistive element R1, the second resistive element R2 and the third resistive element R3 respectively include the first well region W1, the second well region W2 and a third well region W3, and the first well region W1, the second well region W2, and the third well region W3 are connected to the first node N1. The fourth resistive element R4, the fifth resistive element R5, and the sixth resistive element R6 respectively include a fourth well region W4, a fifth well region W5, and a sixth well region W6, and the fourth well region W4, the fifth well region W5, the sixth well region W6 are connected to the second node N2.

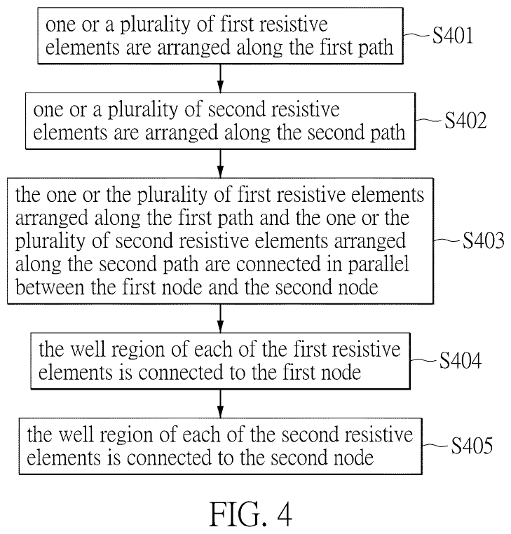

FIG. 4 is a flowchart of a manufacturing method of a resistive circuit that reduces the influence of the well bias effect according to one embodiment of the present disclosure. Referring to FIG. 4, in step S401, one or a plurality of first resistive elements are arranged along the first path L1. In step S402, one or a plurality of second resistive elements are arranged along the second path L2. In step S403, the one or the plurality of first resistive elements arranged along the first path L1 and the one or the plurality of second resistive elements arranged along the second path L2 are connected in parallel between the first node N1 and the second node N2. Each of the one or the plurality of first resistive elements and the one or the plurality of second resistive elements includes a well region. In step S404, the well region of each of the first resistive elements is connected to the first node N1. In step S405, the well region of each of the second resistive elements is connected to the second node N2.

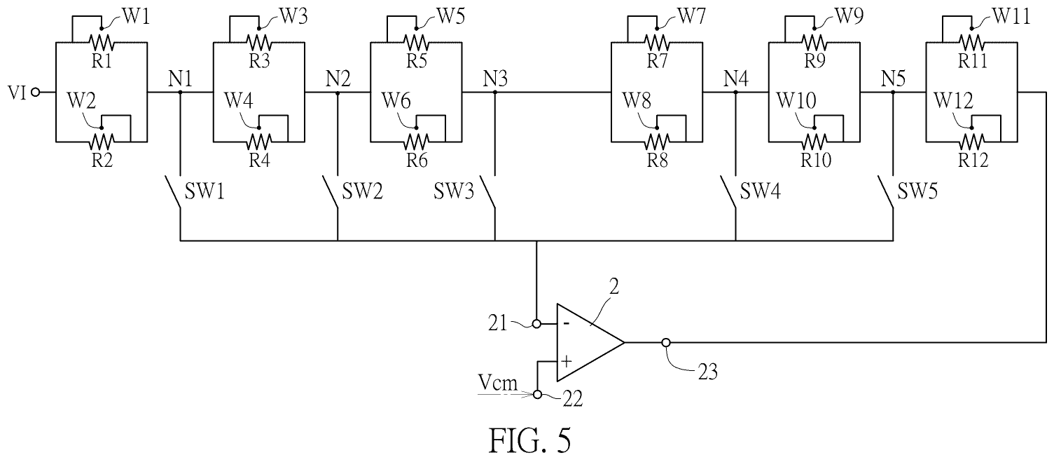

FIG. 5 is a circuit diagram of an amplifier circuit according to a first embodiment of the present disclosure. Referring to FIG. 5, the first resistive element R1 and the second resistive element R2 are connected in parallel between an input signal node V1 and the first node N1, and the first well region W1 of the first resistive element R1 and the second well region W2 of the second resistive element R2 are respectively connected to the input signal node V1 and the first node N1. The first resistive element R1 and the second resistive element R2 have the same rated resistance value.

The third resistive element R3 and the fourth resistive element R4 are connected in parallel between the first node N1 and the second node N2, and the third well region W3 of the third resistive element R3 and the fourth well region W4 of the fourth resistive element R4 are respectively connected to the first node N1 and the second node N2. The third resistive element R3 and the fourth resistive element R4 have the same rated resistance value.

The fifth resistive element R5 and the sixth resistive element R6 are connected in parallel between the second node N2 and a third node N3, and the fifth well region W5 of the fifth resistive element R5 and the sixth well region W6 of the sixth resistive element R6 are respectively connected to the second node N2 and the third node N3. The fifth resistive element R5 and the sixth resistive element R6 have the same rated resistance value.

An operational amplifier 2 includes a first input terminal 21, a second input terminal 22 and an output terminal 23. The first input terminal 21 is an inverting input terminal, and the second input terminal 22 is a non-inverting input terminal and receives a common mode signal Vcm. Two ends of a first switch circuit SW1 are connected to the first node N1 and the first input terminal 21, respectively. Two ends of a second switch circuit SW2 are connected to the second node N2 and the first input terminal 21, respectively. Two ends of a third switch circuit SW3 are connected to the third node N3 and the first input terminal 21, respectively.

A seventh resistive element R7 and an eighth resistive element R8 are connected in parallel between the third node N3 and a fourth node N4. A seventh well region W7 of the seventh resistive element R7 and a eighth well region W8 of the eighth resistive element R8 are respectively connected to the third node N3 and the fourth node N4. The seventh resistive element R7 and the eighth resistive element R8 have the same rated resistance value.

A ninth resistive element R9 and a tenth resistive element R10 are connected in parallel between the fourth node N4 and a fifth node N5. A ninth well region W9 of the ninth resistive element R9 and a tenth well region W10 of the tenth resistive element R10 are respectively connected to the fourth node N4 and the fifth node N5. The ninth resistive element R9 and the tenth resistive element R10 have the same rated resistance value.

An eleventh resistive element R11 and a twelfth resistive element R12 are connected in parallel between the fifth node N5 and the output terminal 23. An eleventh well region W11 of the eleventh resistive element R11 and a twelfth well region W12 of the twelfth resistive element R12 are respectively connected to the fifth node N5 and the output terminal 23. The eleventh resistive element R11 and the twelfth resistive element R12 have the same rated resistance value.

Two ends of a fourth switch circuit SW4 are connected to the fourth node N4 and the first input terminal 21, respectively. Two ends of a fifth switch circuit SW5 are connected to the fifth node N5 and the first input terminal 21, respectively.

Since the second input terminal 22 of the operational amplifier 2 receives the common mode signal Vcm, the amplifier circuit can be applied to a high-speed differential signal pair. In addition, because the amplifier circuit uses the resistive circuit proposed by the present disclosure, the impact of well bias effect on the resistance value can be reduced. Therefore, the gain of the amplifier circuit can be more accurate, and the total harmonic distortion can be reduced for improving signal quality.

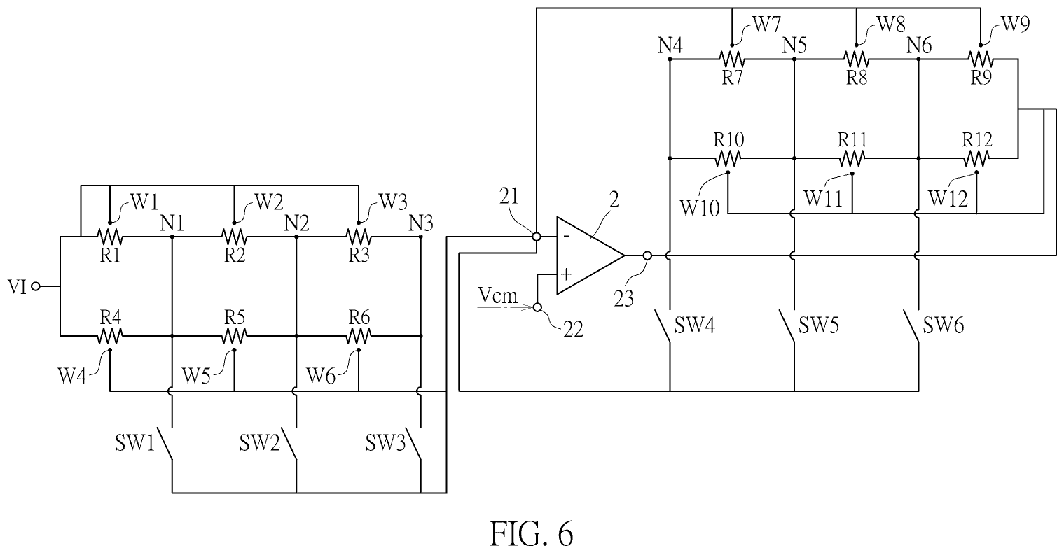

FIG. 6 is a circuit diagram of an amplifier circuit according to a second embodiment of the present disclosure. Referring to FIG. 6, the first resistive element R1 is connected between the input signal node V1 and the first node N1, the second resistive element R2 is connected between the first node N1 and the second node N2, and the third resistive element R3 is connected between the second node N2 and the third node N3. The first well region W1 of the first resistive element R1, the second well region W2 of the second resistive element R2, and the third well region W3 of the third resistive element R3 are all connected to the input signal node V1.

The fourth resistive element R4 is connected between the input signal node V1 and the first node N1, the fifth resistive element R5 is connected between the first node N1 and the second node N2, and the sixth resistive element R6 is connected between the second node N2 and the third node N3. The fourth well region W4 of the fourth resistive element R4, the fifth well region W5 of the fifth resistive element R5, and the sixth well region W6 of the sixth resistive element R6 are all connected to the first input terminal 21.

The two ends of the first switch circuit SW1 are connected to the first node N1 and the first input terminal 21, respectively. The two ends of the second switch circuit SW2 are connected to the second node N2 and the first input terminal 21, respectively. The two ends of the third switch circuit SW3 are connected to the third node N3 and the first input terminal 21, respectively.

The first resistive element R1 and the sixth resistive element R6 have the same rated resistance value, the second resistive element R2 and the fifth resistive element R5 have the same rated resistance value, and the third resistive element R3 and the fourth resistive element R4 have the same rated resistance value.

The seventh resistive element R7 is connected between the fourth node N4 and the fifth node N5, the eighth resistive element R8 is connected between the fifth node N5 and a sixth node N6, and the ninth resistive element R9 is connected between the sixth node N6 and output terminal 23. The seventh well region W7 of the seventh resistive element R7, the eighth well region W8 of the eighth resistive element R8, and the ninth well region W9 of the ninth resistive element R9 are all connected to the first input terminal 21.

The tenth resistive element R10 is connected between the fourth node N4 and the fifth node N5, an eleventh resistive element R11 is connected between the fifth node N5 and the sixth node N6, and a twelfth resistive element R12 is connected between the sixth node N6 and the output terminal 23. The tenth well region W10 of the tenth resistive element R10, an eleventh well region W11 of the eleventh resistive element R11, and a twelfth well region W12 of the twelfth resistive element R12 are all connected to the output terminal 23.

The two ends of the fourth switch circuit SW4 are connected to the fourth node N4 and the first input terminal 21, respectively. The two ends of the fifth switch circuit SW5 are connected to the fifth node N5 and the first input terminal 21, respectively. Two ends of a sixth switch circuit SW6 are connected to the sixth node N6 and the first input terminal 21, respectively.

The seventh resistive element R7 and the twelfth resistive element R12 have the same rated resistance value, the eighth resistive element R8 and the eleventh resistive element R11 have the same rated resistance value, and the ninth resistive element R9 and the tenth resistive element R10 have the same rated resistance value.

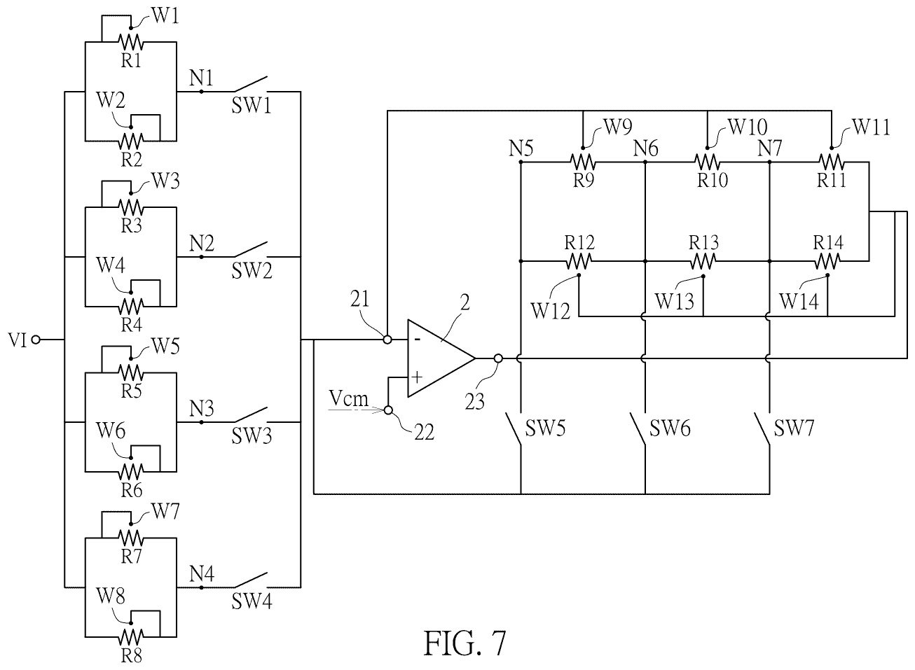

FIG. 7 is a circuit diagram of an amplifier circuit according to a third embodiment of the present disclosure. Referring to FIG. 7, the first resistive element R1 and the second resistive element R2 are connected in parallel between the input signal node V1 and the first node N1, and the first resistive element R1 and the second resistive element R2 have the same rated resistance value. The first well region W1 of the first resistive element R1 is connected to the input signal node V1, and the second well region W2 of the second resistive element R2 is connected to the first node N1.

The third resistive element R3 and the fourth resistive element R4 are connected in parallel between the input signal node V1 and the second node N2, and the third resistive element R3 and the fourth resistive element R4 have the same rated resistance value. The third well region W3 of the third resistive element R3 is connected to the input signal node V1, and the fourth well region W4 of the fourth resistive element R4 is connected to the second node N2.

The fifth resistive element R5 and the sixth resistive element R6 are connected in parallel between the input signal node V1 and the third node N3, and the fifth resistive element R5 and the sixth resistive element R6 have the same rated resistance value. The fifth well region W5 of the fifth resistive element R5 is connected to the input signal node V1, and the sixth well region W6 of the sixth resistive element R6 is connected to the third node N3.

The seventh resistive element R7 and the eighth resistive element R8 are connected in parallel between the input signal node V1 and the fourth node N4, and the seventh resistive element R7 and the eighth resistive element R8 have the same rated resistance value. The seventh well region W7 of the seventh resistive element R7 is connected to the input signal node V1, and the eighth well region W8 of the eighth resistive element R8 is connected to the fourth node N4.

The two ends of the first switch circuit SW1 are connected to the first node N1 and the first input terminal 21, respectively. The two ends of the second switch circuit SW2 are connected to the second node N2 and the first input terminal 21, respectively. The two ends of the third switch circuit SW3 are connected to the third node N3 and the first input terminal 21, respectively. The two ends of the fourth switch circuit SW4 are connected to the fourth node N4 and the first input terminal 21, respectively.

The ninth resistive element R9 is connected between the fifth node N5 and the sixth node N6, the tenth resistive element R10 is connected between the sixth node N6 and a seventh node N7, and the eleventh resistive element R11 is connected between the seventh node N7 and the output terminal 23. The ninth well region W9 of the ninth resistive element R9, the tenth well region W10 of the tenth resistive element R10, and the eleventh well region W11 of the eleventh resistive element R11 are all connected to the first input terminal 21.

The twelfth resistive element R12 is connected between the fifth node N5 and the sixth node N6, a thirteenth resistive element R13 is connected between the sixth node N6 and a seventh node N7, and a fourteenth resistive element R14 is connected between the seventh node N7 and the output terminal 23. The twelfth well region W12 of the twelfth resistive element R12, a thirteenth well region W13 of the thirteenth resistive element R13, and a fourteenth well region W14 of the fourteenth resistive element R14 are all connected to the output terminal 23.

The two ends of the fifth switch circuit SW5 are connected to the fifth node N5 and the first input terminal 21, respectively. The two ends of the sixth switch circuit SW6 are connected to the sixth node N6 and the first input terminal 21, respectively. Two ends of a seventh switch circuit SW7 are connected to the seventh node N7 and the first input terminal 21, respectively.

The ninth resistive element R9 and the fourteenth resistive element R14 have the same rated resistance value, the tenth resistive element R10 and the thirteenth resistive element R13 have the same rated resistance value, and the eleventh resistive element R11 and the twelfth resistive element R12 have the same rated resistance value.

In the above amplifier circuit of FIGS. 5-7, a formula for calculating a voltage value of the output terminal 23 is as follows: (a voltage value of the output terminal 23)=(−1)*(a feedback resistance RFB)/(an input resistance RIN)*(a voltage value of the input signal node V1), wherein the feedback resistance RFB is an equivalent resistance between the first input terminal 21 and the output terminal 23. The input resistance RIN is an equivalent resistance between the input signal node V1 and the first input terminal 21. By using external control signals to switch an off state or an on state of each of the above switch circuits (such as the first switch circuit SW1) configured in the amplifier circuit, (the feedback resistance RFB)/(the input resistance RIN) can be adjusted.

### Beneficial Effects of the Embodiments

In conclusion, in the resistive circuit that reduces the influence of the well bias effect, the manufacturing method of the resistive circuit and the amplifier circuit provided by the present disclosure, the impact of well bias effect on the resistance value of the resistive element can be reduced, such that the linearity of the overall circuit can be improved, and the total harmonic distortion of signal transmission can be reduced.

The foregoing description of the exemplary embodiments of the disclosure has been presented only for the purposes of illustration and description and is not intended to be exhaustive or to limit the disclosure to the precise forms disclosed. Many modifications and variations are possible in light of the above teaching.

The embodiments were chosen and described in order to explain the principles of the disclosure and their practical application so as to enable others skilled in the art to utilize the disclosure and various embodiments and with various modifications as are suited to the particular use contemplated. Alternative embodiments will become apparent to those skilled in the art to which the present disclosure pertains without departing from its spirit and scope.

What is claimed is:

1. A resistive circuit that reduces influence of well bias effect, the resistive circuit comprising:
one or a plurality of first resistive elements arranged in series or in parallel along a first path;
one or a plurality of second resistive elements arranged in series or in parallel along a second path;
wherein the one or the plurality of first resistive elements arranged in series or in parallel along the first path and the one or the plurality of second resistive elements arranged in series or in parallel along the second path are connected in parallel between a first node and a second node;
wherein each of the one or the plurality of first resistive elements and the one or the plurality of second resistive elements include a well region, the well region of each of the plurality of first resistive elements is connected to the first node, and the well region of each of the plurality of second resistive elements is connected to the second node.

2. The resistive circuit according to claim 1, wherein a quantity of the one or the plurality of first resistive elements is same as a quantity of the one or the plurality of second resistive elements.

3. The resistive circuit according to claim 2, wherein, when the quantity of the one or the plurality of first resistive elements and the quantity of the one or the plurality of second resistive elements are both one, the first resistive element and the second resistive element have same resistance value under a predetermined condition.

4. The resistive circuit according to claim 3, wherein, when the quantity of the one or the plurality of first resistive elements and the quantity of the one or the plurality of second resistive elements are both greater than one, the plurality of first resistive elements are connected in parallel or in series along the first path, and the plurality of second resistive elements are connected in parallel or in series along the second path.

5. The resistive circuit according to claim 4, wherein a plurality of first resistance values of the plurality of first resistive elements under the predetermined condition respectively correspond to a plurality of second resistance values of the plurality of second resistive elements under the predetermined condition.

6. The resistive circuit according to claim 4, wherein a plurality of first resistance values of the plurality of first resistive elements and a plurality of second resistance values of the plurality of second resistive elements are the same.

7. The resistive circuit according to claim 4, wherein a plurality of first resistance values of the plurality of first resistive elements are not all same.

8. An amplifier circuit comprising:
an operational amplifier including a first input terminal, a second input terminal and an output terminal;
one or a plurality of first resistors connected between the first input terminal and a signal input node;
one or a plurality of second resistors connected between the first input terminal and the output terminal;
wherein each of the one or the plurality of first resistors and the one or the plurality of second resistors is the resistive circuit as claimed in claim 1.

9. The amplifier circuit according to claim 8, further comprising:
one or a plurality of first switches corresponding to the one or the plurality of first resistors, each of the plurality of first switches being connected between the corresponding first resistor and the first input terminal; and
one or a plurality of second switches corresponding to the one or the plurality of second resistors, each of the plurality of second switches being connected between the corresponding second resistor and the first input terminal.

10. A manufacturing method of a resistive circuit that reduces influence of well bias effect, the manufacturing method comprising:
arranging one or a plurality of first resistive elements in series or parallel along a first path;
arranging one or a plurality of second resistive elements in series or parallel along a second path;
connecting the one or the plurality of first resistive elements arranged in series or parallel along the first path and the one or the plurality of second resistive elements arranged in series or parallel along the second path in parallel between a first node and a second node;
wherein each of the one or the plurality of first resistive elements and the one or the plurality of second resistive elements includes a well region;
connecting the well region of each of the one or the plurality of first resistive elements to the first node; and
connecting the well region of each of the one or the plurality of second resistive elements to the second node.

11. The manufacturing method according to claim 10, wherein a quantity of the one or the plurality of first resistive elements is same as a quantity of the one or the plurality of second resistive elements.

12. The manufacturing method according to claim 11, wherein, when the quantity of the one or the plurality of first resistive elements and the quantity of the one or the plurality of second resistive elements are both one, the first resistive element and the second resistive element have the same resistance value under a predetermined condition.

13. The manufacturing method according to claim 12, wherein, when the quantity of the one or the plurality of first resistive elements and the quantity of the one or the plurality of second resistive elements are both greater than one, the plurality of first resistive elements are connected in parallel or in series along the first path, and the plurality of second resistive elements are connected in parallel or in series along the second path.

14. The manufacturing method according to claim 13, wherein a plurality of first resistance values of the plurality of first resistive elements under the predetermined condition respectively correspond to a plurality of second resistance values of the plurality of second resistive elements under the predetermined condition.

15. The manufacturing method according to claim 13, wherein the plurality of first resistance values of the plurality of first resistive elements and the plurality of second resistance values of the plurality of second resistive elements are the same.

16. The manufacturing method according to claim 13, wherein the plurality of first resistance values of the plurality of first resistive elements are not all the same.
